(19) United States
(12) Patent Application Publication
(10) Pub. No.: US 2010/0072525 A1
(43) Pub. Date: Mar. 25, 2010

(54) SEMICONDUCTOR MEMORY DEVICE AND METHOD FOR MANUFACTURING THE SAME

(75) Inventors: Yoshiro Shimojo, Yokohama-Shi (JP); Tohru Ozaki, Tokyo (JP); Yoshinori Kumura, Albany, CA (US)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/553,923

(22) Filed: Sep. 3, 2009

(30) Foreign Application Priority Data
Sep. 25, 2008 (JP) 2008-246321

(51) Int. Cl. H01L 27/108; H01L 21/02

(52) U.S. Cl. 257/295; 438/3; 257/E27.084; 257/E21.009

(57) ABSTRACT

According to a method for manufacturing a semiconductor memory device of the present invention, a capacitor lower electrode film is left on the wiring layer located above a dummy transistor. In this manner, when processing of the capacitors is performed by removing a capacitor upper electrode film and a ferroelectric film, removal of the wiring layer can be prevented, and the connection between the diffusion layer of a select transistor and a bit line can be secured.

### CROSS REFERENCE TO RELATED APPLICATION

This application is based upon and claims benefit of priority from the Japanese Application No. 2008-246321, filed on Sep. 25, 2008, the entire contents of which are incorporated herein by reference.

### BACKGROUND OF THE INVENTION

The present invention relates to a semiconductor memory device and a method for manufacturing the same.

In recent years, attention is drawn to ferroelectric memories (or FeRAM: Ferroelectric Random Access Memory) as one type of semiconductor memories. A ferroelectric memory is a nonvolatile memory that includes a ferroelectric film such as a PZT (Pb(ZrₓTi₁₋ₓ)O₃) film, a BIT (Bi₄Ti₃O₁₂) film, or a SBT (SrBi₂Ta₂O₉) film at each capacitor portion, and stores data by virtue of the residual polarization of the ferroelectric film.

As one example structure of FeRAM, there is a known structure in which each ring connecting a transistor and a capacitor in parallel is set as a memory cell, and several (eight, for example) memory cells are connected in series (see JP-A 10-255483, for example). The transistor of each of the memory cells is formed in a surface portion of a semiconductor substrate, and the capacitor is formed above the transistor. The upper electrode of the capacitor is connected to one of the source/drain diffusion layers of the transistor, and the lower electrode of the capacitor is connected to the other one of the source/drain diffusion layers of the transistor.

In a memory block formed with memory cells connected in series, the memory cell at one end of the block is connected to a plate line, and the memory cell at the other end is connected to a bit line via a select transistor that selects the block.

A method for manufacturing FeRAM of such a structure is now described. First, transistors are formed at predetermined intervals on a semiconductor substrate. The transistors are then covered with a first insulating film, and first contact plugs to be connected to the source/drain diffusion layers of the respective transistors are formed. Here, n (n being an integer of 2 or greater) transistors adjacent to one another among the transistors are the transistors of the memory cells forming a memory block. The transistor adjacent to the transistor at one end of the memory block is a select transistor, and the transistor adjacent to the select transistor is a dummy transistor.

A second insulating film is formed on the first contact plugs and the first insulating film, and openings to expose the upper faces of the first contact plugs are formed above the respective first contact plugs. The openings are filled with metal film, so as to form first wiring layers.

In the opening pattern in the memory cell formation area, narrow openings and wide openings are alternately formed. Accordingly, in the memory cell formation area, wide wirings and narrow wirings are alternately formed as the first wiring layers.

An opening is also formed to expose the upper face of the first conduct plug connected to the source diffusion layer of the dummy transistor and the upper face of the first conduct plug connected to the drain diffusion layer of the dummy transistor. Accordingly, the first contact plug connected to the source diffusion layer of the dummy transistor and the first contact plug connected to the drain diffusion layer of the dummy transistor are connected to each other by a first wiring layer.

A lower electrode film, a ferroelectric film, and an upper electrode film are stacked in this order on the first wiring layers and the second insulating film. The portions of the upper electrode film, the ferroelectric film, and the lower electrode film outside the regions located above the gate electrodes of the transistors are removed, and capacitor processing is performed. In this manner, capacitors are formed above the gate electrodes of the transistors. Two capacitors are formed on each of the wide wirings of the first wiring layers. Accordingly, each of the wide wirings of the first wiring layers connects the lower electrodes of each corresponding two adjacent capacitors. The lower electrode of the capacitor formed above the gate electrode of the select transistor and the lower electrode of the capacitor formed above the gate electrode of the dummy transistor are connected to each other by one of the first wiring layers.

Through the capacitor processing, the upper face of the first wiring layer located in the region above one of the source/drain diffusion layers of the dummy transistor (or above the diffusion layer of the dummy transistor that is neither the source diffusion layer nor the drain diffusion layer of the select transistor) is exposed.

A third insulating film is then formed to cover the capacitors, and second contact plugs to be connected to the upper electrodes of the respective capacitors are formed. However, the capacitor formed above the gate electrode of the select transistor, and the capacitor formed above the gate electrode of the dummy transistor are dummy capacitors. Therefore, second contact plugs are not formed on those capacitors.

Openings are then formed to expose the upper faces of the narrow wirings of the first wiring layers, and upper faces of the portions exposed at the time of capacitor processing. The openings are filled with metal film, so as to form third contact plugs.

A fourth insulating film is formed on the third insulating film, the second contact plugs, and the third contact plugs. Openings are formed to expose the upper faces of the second contact plugs and the third contact plugs. The openings are filled with metal film, so as to form second wiring layers.

In the opening pattern in the memory cell formation area, adjacent openings are formed to expose the upper face of each third contact plug and the upper faces of the two second contact plugs located on both sides of each third contact plug. Accordingly, in the memory cell formation area, each third contact plug is connected to the second contact plugs located on both sides of the third contact plug by a second wiring layer.

In this manner, it is possible to produce a structure in which memory cells each including a transistor and a capacitor connected in parallel are connected in series.

The second wiring layer connected to the third contact plug located above the source/drain diffusion layers of the dummy transistor is connected to a bit line in a later procedure. Accordingly, one of the source/drain diffusion layers of the select transistor is connected to the bit line via the first contact plug, the first wiring layer, and the third contact plug. Thus, data reading and writing are enabled.

By this conventional manufacture method, however, when the capacitor processing is performed to expose the upper face of the first wiring layer in the region located above one of the source/drain diffusion layers of the dummy transistor, the first wiring layer might be completely removed. In such a case, the third contact plug is not brought into contact with the first wiring layer, and one of the source/drain diffusion layers of the select transistor is not connected to the bit line. As a result, problems are caused, as data reading and writing are disabled, and the production yield is lowered.

### SUMMARY OF THE INVENTION

According to one aspect of the present invention, there is provided a semiconductor memory device comprising:

a semiconductor substrate;

first through fourth impurity diffusion layers that are formed at predetermined intervals in surface portions of the semiconductor substrate;

a first gate electrode that is formed on a portion of the semiconductor substrate, the portion being located between the first impurity diffusion layer and the second impurity diffusion layer;

a second gate electrode that is formed on a portion of the semiconductor substrate, the portion being located between the second impurity diffusion layer and the third impurity diffusion layer;

a third gate electrode that is formed on a portion of the semiconductor substrate, the portion being located between the third impurity diffusion layer and the fourth impurity diffusion layer;

a first insulating film that is formed on the semiconductor substrate, to cover the first through third gate electrodes;

a first contact plug that penetrates through the first insulating film, and is in contact with the first impurity diffusion layer;

a second contact plug that penetrates through the first insulating film, and is in contact with the second impurity diffusion layer;

a third contact plug that penetrates through the first insulating film, and is in contact with the third impurity diffusion layer;

a fourth contact plug that penetrates through the first insulating film, and is in contact with the fourth impurity diffusion layer;

a first metal film that is formed on the first contact plug;

a second metal film that is formed on the second contact plug;

a third metal film that is formed on the third contact plug, a portion of the first insulating film located between the third contact plug and the fourth contact plug, and the fourth contact plug;

a capacitor lower electrode film that is formed on the first metal film;

a fourth metal film that is formed on the third metal film, and is made of the same material as the capacitor lower electrode film;

a ferroelectric film that is formed on a region of the capacitor lower electrode film, the region being located above the first gate electrode;

a capacitor upper electrode film that is formed on the ferroelectric film;

a second insulating film that is formed on the capacitor lower electrode film, to cover the capacitor upper electrode film and the ferroelectric film;

a third insulating film that is formed on the fourth metal film, and is made of the same material as the second insulating film;

a fourth insulating film that is formed to cover the second insulating film, the third insulating film, and the second metal film;

a fifth contact plug that penetrates through the fourth insulating film and the second insulating film, and is in contact with the capacitor upper electrode film;

a sixth contact plug that penetrates through the fourth insulating film, and is in contact with the second metal film;

a seventh contact plug that penetrates through the fourth insulating film and the third insulating film, and is in contact with the fourth metal film;

a fifth metal film that is formed on the fifth contact plug, a portion of the fourth insulating film located between the fifth contact plug and the sixth contact plug, and the sixth contact plug; and

a sixth metal film that is formed on the seventh contact plug, and is connected to a bit line.

According to one aspect of the present invention, there is provided a method for manufacturing a semiconductor memory device, comprising:

forming first through third gate electrodes at predetermined intervals on a semiconductor substrate via a gate insulating film;

forming a first impurity diffusion layer, a second impurity diffusion layer, a third impurity diffusion layer, and a fourth impurity diffusion layer in surface portions of the semiconductor substrate by injecting impurities into the semiconductor substrate, with the first through third gate electrodes serving as masks, the first impurity diffusion layer and the second impurity diffusion layer sandwiching the first gate electrode, the third impurity diffusion layer and the fourth impurity diffusion layer sandwiching the third gate electrode;

forming a first insulating film to cover the first through third gate electrodes and the first through fourth impurity diffusion layers;

forming first through fourth openings that penetrate through the first insulating film, and expose upper faces of the first through fourth impurity diffusion layers;

forming first through fourth contact plugs by filling the first through fourth openings with a first metal film;

forming a second insulating film on the first through fourth contact plugs and the first insulating film;

forming a fifth opening to expose an upper face of the first contact plug, a sixth opening to expose an upper face of the second contact plug, and a seventh opening to expose an upper face of the third contact plug, an upper face of the first insulating film located between the third contact plug and the fourth contact plug, and an upper face of the fourth contact plug;

forming first through third wirings by filling the fifth through seventh openings with a second metal film;

forming a capacitor lower electrode film on the first through third wirings and the second insulating film;

forming a ferroelectric film on the capacitor lower electrode film;

forming a capacitor upper electrode film on the ferroelectric film;

removing portions of the capacitor upper electrode film and the ferroelectric film, the portions being located outside a region above the first gate electrode;

forming a third insulating film to cover the capacitor upper electrode film and the ferroelectric film, the third insulating film being formed on regions of the capacitor lower electrode film, the regions being located above the first wiring and the third wiring;

partially removing the capacitor lower electrode film, with the third insulating film serving as a mask;

forming a fourth insulating film to cover the third insulating film, the second insulating film, and the second wiring;

forming an eighth opening that penetrates through the fourth insulating film and the third insulating film, and exposes an upper face of the capacitor upper electrode film;

forming a fifth contact plug by filling the eighth opening with a third metal film;

forming a ninth opening that penetrates through the fourth insulating film and exposes an upper face of the second wiring, and a tenth opening that penetrates through the fourth insulating film and the third insulating film, and exposes an upper face of the capacitor lower electrode film located in a region above the fourth contact plug;

forming sixth and seventh contact plugs by filling the ninth and tenth openings with a fourth metal film;

forming a fifth insulating film on the fifth through seventh contact plugs and the fourth insulating film;

forming an eleventh opening that exposes an upper face of the fifth contact plug, an upper face of the fourth insulating film located between the fifth contact plug and the sixth contact plug, and an eleventh opening that exposes an upper face of the sixth contact plug, and a twelfth opening that exposes an upper face of the seventh contact plug; and

forming fourth and fifth wirings by filling the eleventh and twelfth openings with a fifth metal film.

### BRIEF DESCRIPTION OF THE DRAWINGS

FIG. 1 is a cross-sectional view illustrating a manufacturing procedure in a method for manufacturing a semiconductor memory device in accordance with an embodiment of the present invention;

FIG. 2 is a cross-sectional view showing a step subsequent to FIG. 1;

FIG. 3 is a cross-sectional view showing a step subsequent to FIG. 2;

FIG. 4 is a cross-sectional view showing a step subsequent to FIG. 3;

FIG. 5 is a cross-sectional view showing a step subsequent to FIG. 4;

FIG. 6 is a cross-sectional view showing a step subsequent to FIG. 5;

FIG. 7 is a cross-sectional view showing a step subsequent to FIG. 6;

FIG. 8 is a cross-sectional view showing a step subsequent to FIG. 7;

FIG. 9 is a cross-sectional view showing a step subsequent to FIG. 8;

FIG. 10 is a cross-sectional view showing a step subsequent to FIG. 9;

FIG. 11 is a cross-sectional view illustrating a manufacturing procedure in a method for manufacturing a semiconductor memory device in accordance with a comparative example;

FIG. 12 is a cross-sectional view showing a step subsequent to FIG. 11;

FIG. 13 is a cross-sectional view showing a step subsequent to FIG. 12;

FIG. 14 is a cross-sectional view showing a step subsequent to FIG. 13;

FIG. 15 is a cross-sectional view showing a step subsequent to FIG. 14;

FIG. 16 is a vertical cross-sectional view of a semiconductor memory device in accordance with a modification; and

FIG. 17 is a vertical cross-sectional view of a semiconductor memory device in accordance with a modification.

### DESCRIPTION OF THE EMBODIMENTS

The following is a description of embodiments of the present invention, with reference to the accompanying drawings.

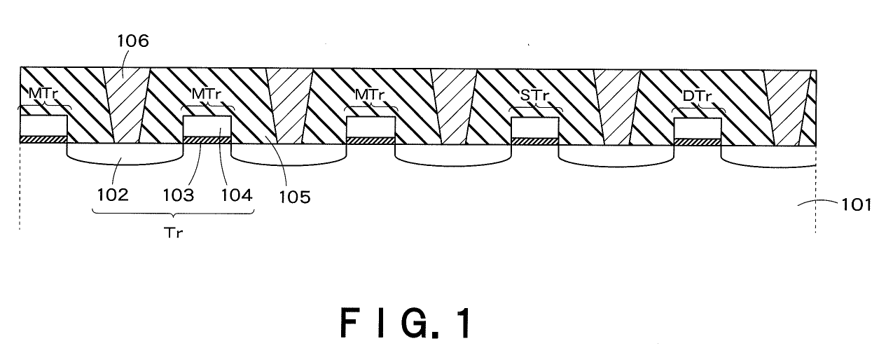

Referring to the cross-sectional views illustrating manufacturing procedures in FIGS. 1 through 10, a method for manufacturing a semiconductor memory device in accordance with an embodiment of the present invention is described. The semiconductor memory device to be manufactured in accordance with this embodiment is a FeRAM of a TC parallel unit series-connected structure having memory cells (eight memory cells, for example) connected in series. Each of the memory cells is formed with a ring that connects a transistor and a capacitor in parallel to each other.

As shown in FIG. 1, transistors Tr are formed at predetermined intervals on a semiconductor substrate 101 by a known CMOS process. Each of the transistors Tr includes source/drain diffusion layers 102 formed in surface portions of the semiconductor substrate 101, a gate insulating film 103 formed on the portion of the semiconductor substrate 101 located between the source/drain diffusion layers 102, and a gate electrode 104 formed on the gate insulating film 103. The source/drain diffusion layers 102 are formed by injecting impurities into the semiconductor substrate 101, with the gate electrode 104 serving as a mask.

Transistors MTr are the transistors included in the memory cells, and several continuous (series-connected) memory cells constitute one memory block. The transistor STr adjacent to the transistor MTr of the memory cell located at an end of the memory block is a select transistor, and the transistor DTr adjacent to the transistor STr is a dummy transistor.

An insulating film 105 made of silicon oxide, for example, is then formed to cover the transistors, and contact holes are formed to partially expose the upper faces of the source/drain diffusion layers 102. The contact holes are filled with metal film (such as tungsten film) by Chemical Vapor Deposition (CVD), so as to form contact plugs 106.

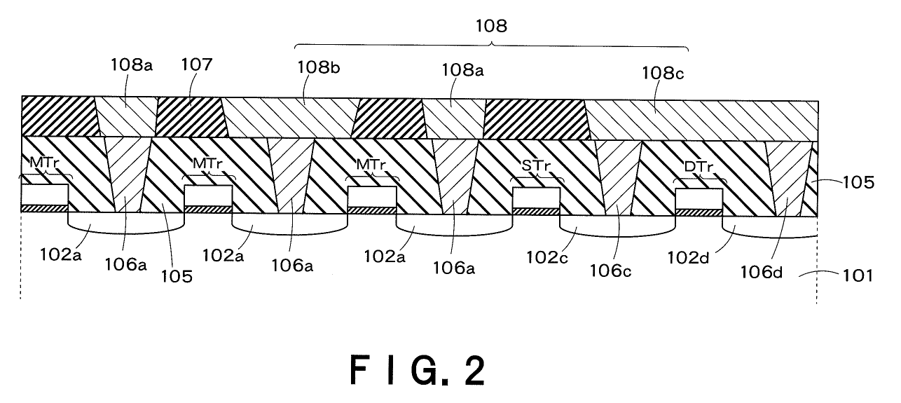

As shown in FIG. 2, an insulating film 107 made of silicon oxide, for example, is formed over the insulating film 105 and the contact plugs 106 (106a, 106c, and 106d). Openings are then formed to expose the upper faces of the contact plugs 106. The openings are filled with metal film (such as tungsten film) by CVD, so as to form wiring layers 108.

Of the wiring layers 108, narrow wiring layers 108a and wide wiring layers 108b are alternately formed on the contact plugs 106a connected to the source/drain diffusion layers 102a of the transistors MTr.

A wiring layer 108c is also formed to connect the contact plug 106c connected to the diffusion layer 102c located between the gate electrodes of the transistor STr and the transistor DTr to the contact plug 106d connected to the diffusion layer 102d located on the opposite side of the dummy transistor DTr from the transistor STr.

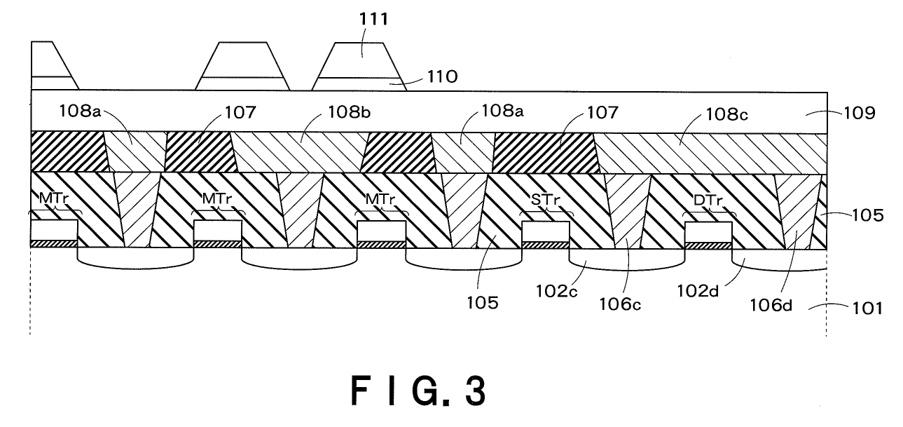

As shown in FIG. 3, a lower electrode film 109, a ferroelectric film 110, and an upper electrode film 111 are stacked in this order over the insulating film 107 and the wiring layers 108. The lower electrode film 109 and the upper electrode film 111 are made of Ir, for example, and the ferroelectric film 110 is made of PZT, for example.

The portions of the upper electrode film 111 and the ferroelectric film 110 located outside the regions over the gate electrodes of the transistors MTr are removed by a lithography technique. The patterning of the upper electrode film 111 and the ferroelectric film 110 may be performed through a room-temperature process with the use of a resist, or a hard-mask process with the use of oxide film, alumina, and a conductive metal.

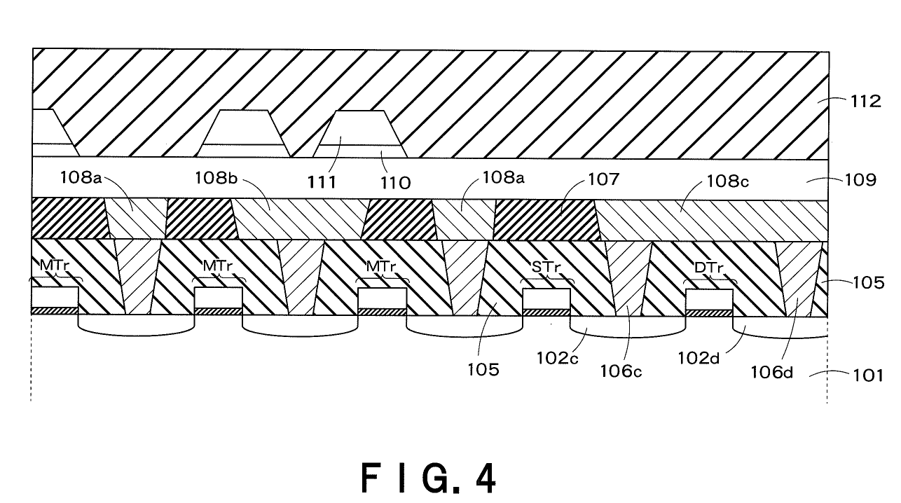

As shown in FIG. 4, an insulating film 112 made of TEOS, for example, is formed to cover the lower electrode film 109, the ferroelectric film 110, and the upper electrode film 111. The insulating film 112 is then flattened by CMP (Chemical Mechanical Polishing).

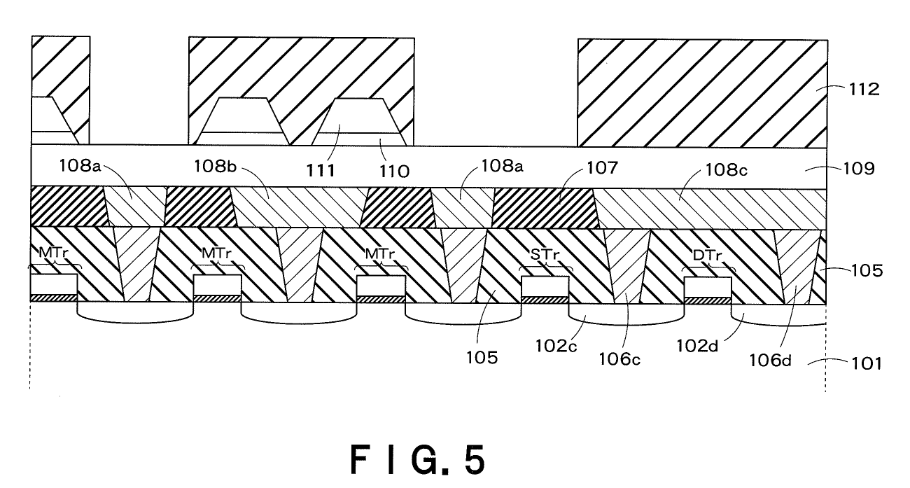

As shown in FIG. 5, resists (not shown) are formed on the portions of the insulating film 112 located immediately above the wiring layer 108b and the wiring layer 108c. With the resists serving as masks, etching is performed on the insulating film 112. The resists are then removed.

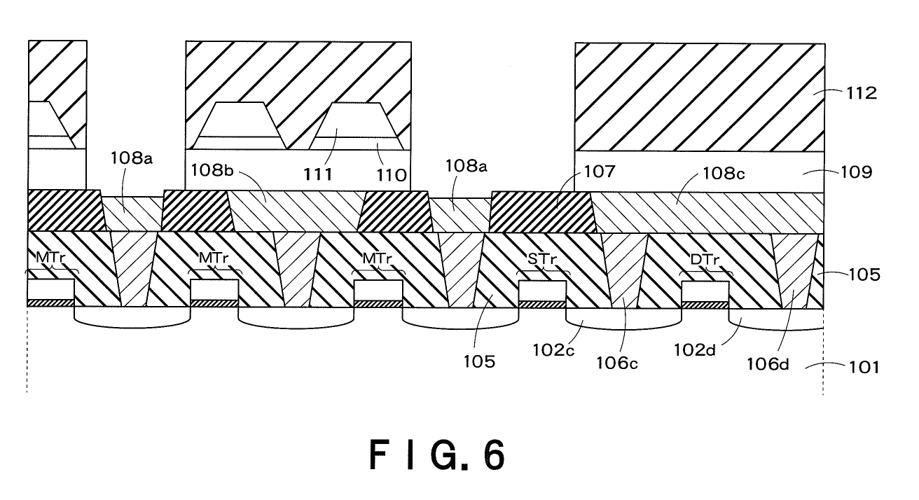

As shown in FIG. 6, with the insulating film 112 serving as a mask, Reactive Ion Etching (RIE) is performed on the lower electrode film 109, for example. At this point, the wiring layers 108a might be partially removed.

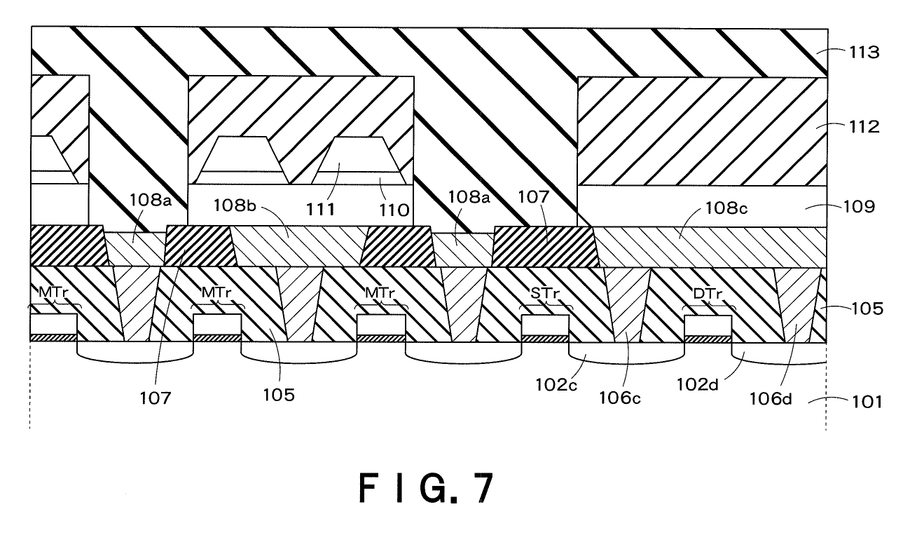

As shown in FIG. 7, an insulating film 113 made of silicon oxide, for example, is formed to cover the insulating film 112, the wiring layers 108a, and the insulating film 107. The insulating film 113 is then flattened by CMP.

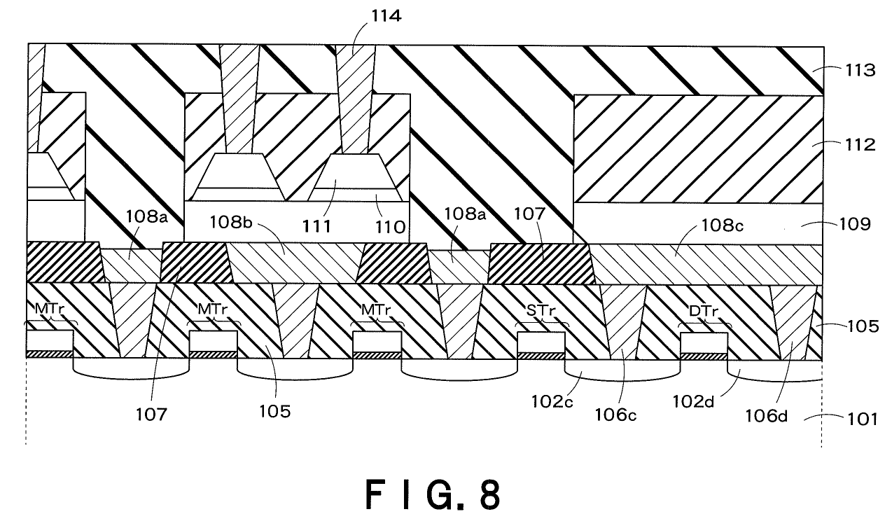

As shown in FIG. 8, openings are formed to expose the upper faces of the upper electrode film 11. The openings are filled with metal film (such as tungsten film) by CVD, so as to form contact plugs 114.

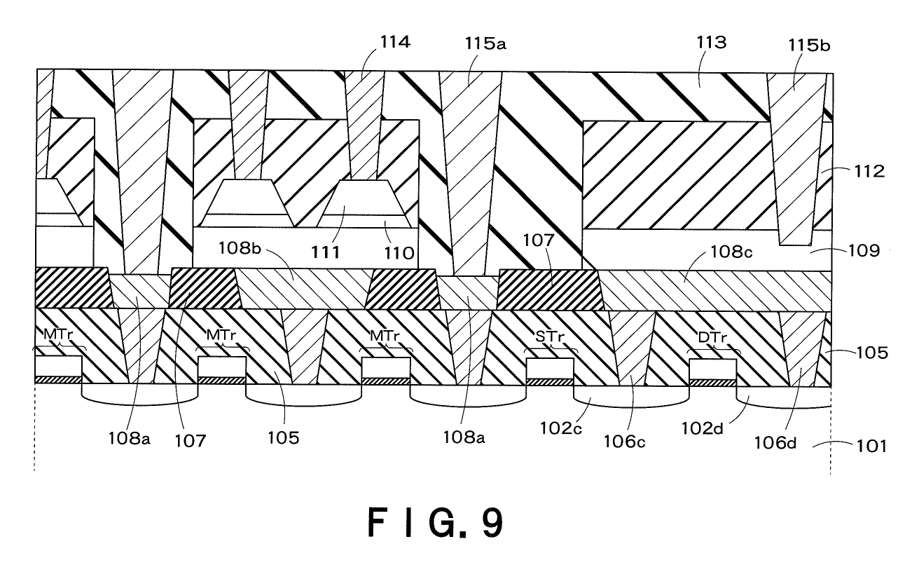

As shown in FIG. 9, openings are formed to partially expose upper faces of the wiring layers 108a and the upper face of the wiring layer 108c above the contact plug 106d. The openings are filled with metal film (such as tungsten film) by CVD, so as to form contact plugs 115a and 115b.

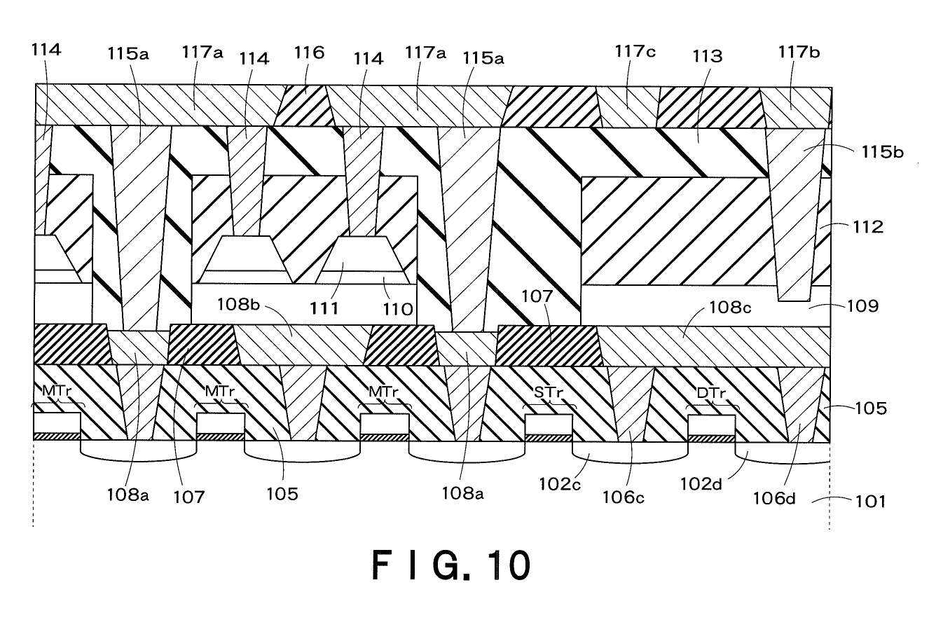

As shown in FIG. 10, an insulating film 116 made of silicon oxide, for example, is formed on the insulating film 113 and the contact plugs 114, 115a, and 115b. Openings are formed to expose the upper faces of the contact plugs 114, 115a, and 115b. The openings are filled with metal film (such as tungsten film) by CVD, so as to form wiring layers 117a through 117c.

Here, the openings are formed to expose the upper faces of the contact plugs 115a and the contact plugs 114 on both sides of the respective contact plugs 115a. The wirings layers 117a formed in the openings connect the contact plugs 115a to the contact plugs 114 located on both sides of the respective contact plugs 115a.

Above the transistor MTr at the end of the memory block, the wiring layer 117a connects the contact plug 115a to one of the contact plugs 114.

In this structure, the upper electrode 111 of the capacitor is connected to one of the source/drain diffusion layers 102 of the transistor MTr below the capacitor, and the lower electrode film 109 of the capacitor is connected to the other one of the source/drain diffusion layers 102 of the transistor MTr below the capacitor. Accordingly, the capacitor and the transistor MTr are connected in parallel, so as to form a memory cell.

The wiring layer 117b is formed on the contact plug 115b, and the wiring layer 117c is formed on the portion located above the contact plug 106c.

After that, a bit line contact (not shown) to be connected to a bit line is formed on the wiring layer 117b. The diffusion layers 102c of the transistor STr are connected to the bit line via the contact plug 106c, the wiring layer 108c, the lower electrode film 109, the contact plug 115b, the wiring layer 117b, and the likes. Thus, data reading and writing are enabled.

Since the lower electrode film 109 remains on the wiring layer 108c, removal and loss of the wiring layer 108c can be prevented when processing is performed on the upper electrode film and the ferroelectric film of the capacitor. Thus, the connection between the diffusion layers 102c of the transistor STr serving as the select transistor and the bit line is secured.

### Comparative Example

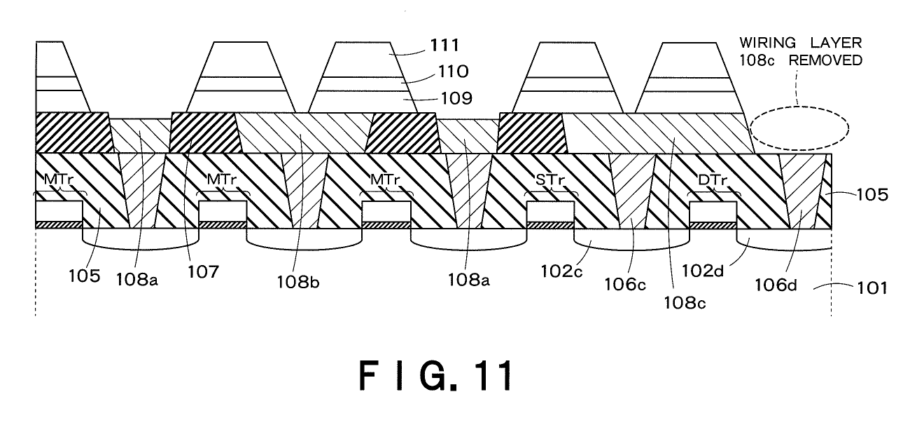

Referring now to the cross-sectional views illustrating the manufacturing procedures in FIGS. 11 through 15, a method for manufacturing a semiconductor memory device in accordance with a comparative example is described. The procedures up to the formation of the insulating film 107 and the wiring layers 108a through 108c are the same as those of the above described embodiment (see FIGS. 1 and 2), and therefore, explanation of them is not repeated herein.

As shown in FIG. 11, a lower electrode film 109, a ferroelectric film 110, and an upper electrode film 111 are stacked in this order over the insulating film 107 and the wiring layers 108a through 108c. Etching is then performed by a lithography technique, so as to remove the portions of the upper electrode film 111, the ferroelectric film 110, and the lower electrode film 109 outside the regions located above the gate electrodes of the transistors MTr, STr, and DTr. Processing of the capacitors is then performed.

During the processing of the capacitors, the etching does not stop at the lower electrode film 109, and reaches and removes the wiring layer 108c in the region located above the contact plug 106d.

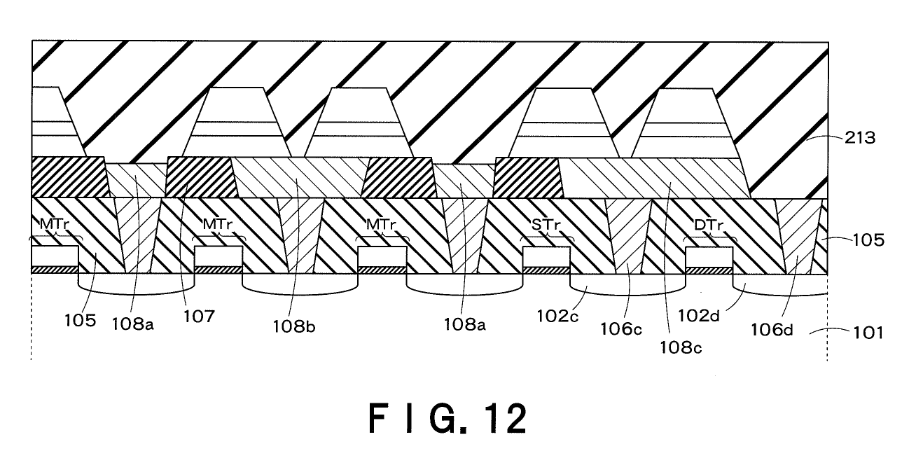

As shown in FIG. 12, an insulating film 213 made of silicon oxide, for example is formed to cover the capacitor. The insulating film 213 is then flattened by CMP.

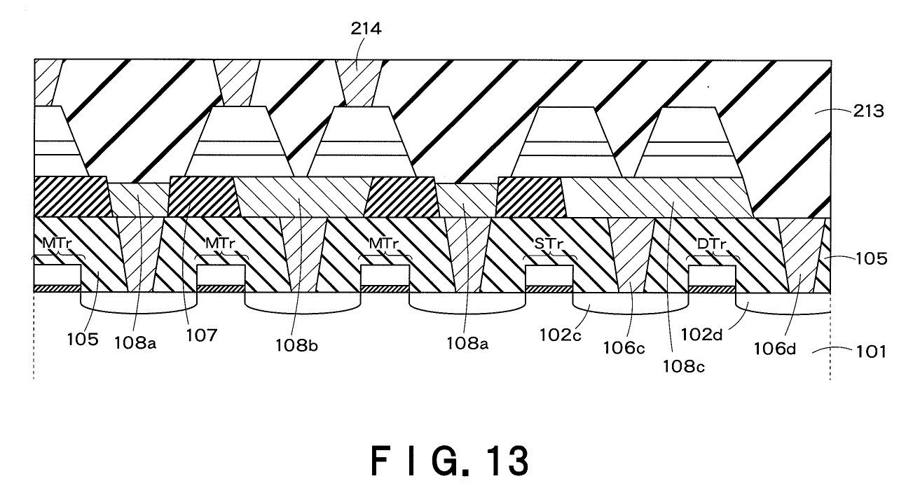

As shown in FIG. 13, openings are formed to partially expose the upper face of the upper electrode film 111. The openings are filled with metal film (such as tungsten film) by CVD, so as to form contact plugs 214. Since the capacitors on the transistor STr and the transistor DTr are dummy capacitors, contact plugs 214 in contact with the upper electrode film 111 of those capacitors are not formed.

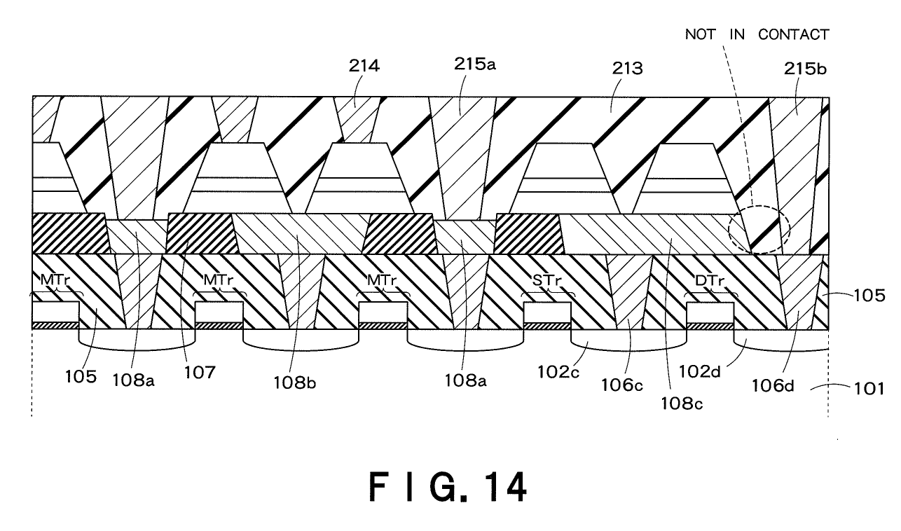

As shown in FIG. 14, an opening is formed to partially expose the upper face of the wiring layer 108a. The opening is filled with metal film (such as tungsten film) by CVD, so as to form a contact plug 215a.

At the same time, an opening is formed above the contact plug 106d. However, the wiring layer 108c formed on the region located above the contact plug 106d has already been removed during the procedure illustrated in FIG. 11. As a result, a contact plug 215b that is in contact with the contact plug 106d, instead of the wiring layer 108c, is formed.

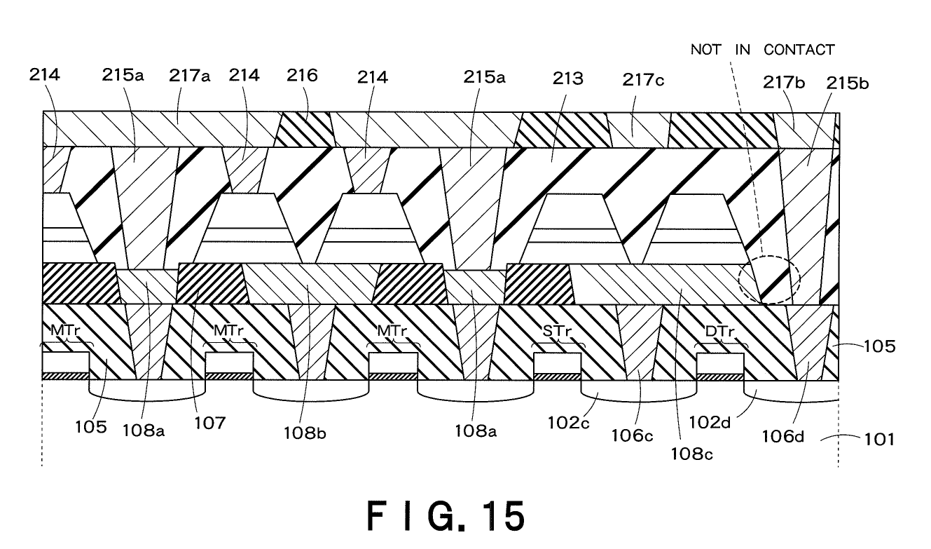

As shown in FIG. 15, an insulating film 216 made of silicon oxide, for example, is formed on the insulating film 213, the contact plugs 214, 215a, and 215b. Openings are then formed to expose the upper faces of the contact plugs 214, 215a, and 215b. The openings are filled with metal film (such as tungsten film) by CVD, so as to form wiring layers 217a through 217c.

Here, the openings are formed to expose the upper faces of the contact plugs 215a and the contact plugs 214 on both sides of each contact plug 215a. Each of the wiring layer 217a formed in those openings connects the corresponding contact plug 215a to the two contact plugs 214 located on both sides of the contact plug 215a.

In this structure, the upper electrode film 111 of each capacitor is connected to one of the source/drain diffusion layers 102 of the corresponding transistor MTr located below the capacitor, and the lower electrode film 109 of the capacitor is connected to the other one of the source/drain diffusion layers 102 of the transistor MTr located below the capacitor. Thus, the capacitor and the transistor MTr are connected in parallel.

The wiring layer 217b is formed on the contact plug 215b, and the wiring layer 217c is formed in the region located above the contact plug 106c. After that, a bit line contact (not shown) to be connected to a bit line is formed on the wiring layer 217b.

However, the wiring layer 108c in the region located above the contact plug 106d has already been removed during the procedure illustrated in FIG. 11. Therefore, the contact plug 215b is not connected to (not in contact with) the wiring layer 108c. As a result, the diffusion layers 102c of the transistor STr serving as the select transistor are not connected to the bit line, and data reading and writing are disabled.

In the above described embodiment, the lower electrode film 109 remains above the transistor DTr (see FIGS. 3 and 6), so as to prevent removal of the wiring layer 108c. Thus, the connection between the bit line and the diffusion layers 102c of the transistor STr serving as the select transistor can be secured.

As described above, the method for manufacturing the semiconductor memory device in accordance with this embodiment can prevent defective contact between the diffusion layers of the select transistor and the bit line, and can increase the production yield.

In the above embodiment, Al₂O₃ may be used for the insulating film 112 formed in the procedure illustrated in FIG. 4. Having barrier properties against hydrogen, Al₂O₃ can prevent damage to the capacitors.

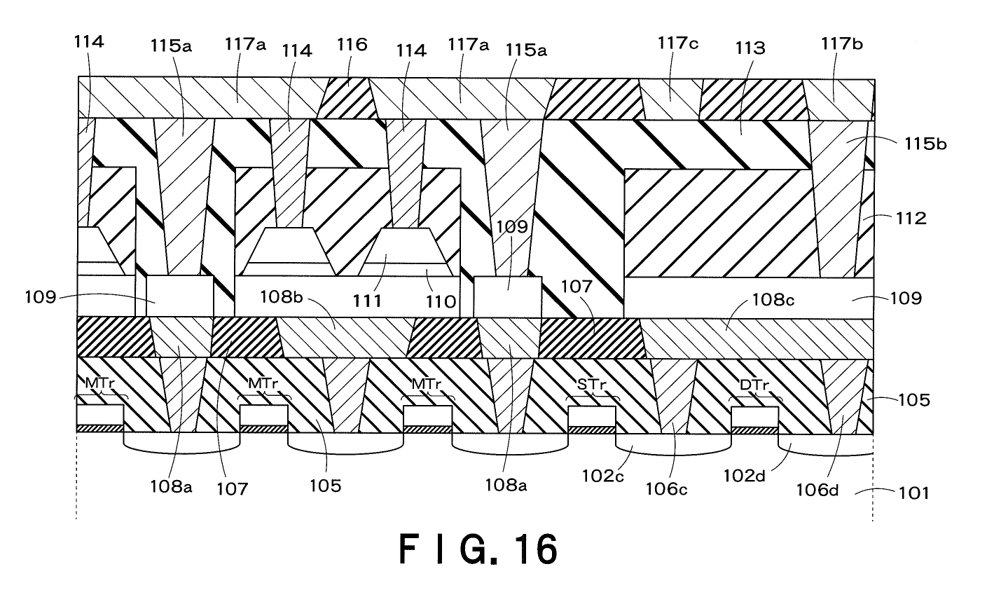

When patterning is performed on the insulating film 112 in the procedure illustrated in FIG. 5, the insulating film 112 may be formed above the wiring layers 108a, so that the lower electrode film 109 also remains on the wiring layers 108a. In this manner, partial removal of the wiring layers 108a can be prevented in the procedure for removing the lower electrode film 109 in FIG. 6, and the contact margin of each contact plug 115a can be increased. By such a manufacture method, the semiconductor memory device shown in FIG. 16 is produced.

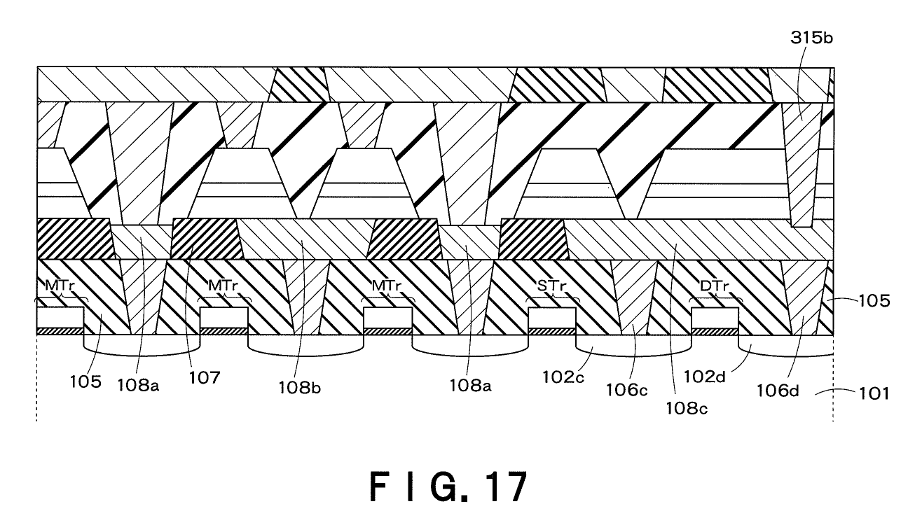

Also, as shown in FIG. 17, the portion of the wiring layer 108c located above the contact plug 106d may be covered with a dummy capacitor. With this arrangement, removal of the wiring layer 108c can also be prevented, and the connection between the bit line and the diffusion layers 102c of the transistors STr serving as the select transistor can be secured. However, when the contact hole for the contact plug 315b is formed, it is necessary to prepare such a hard mask and selectivity as to penetrate through the upper electrode film 111, the ferroelectric film 110, and the lower electrode film 109 of the capacitor.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a semiconductor substrate;
first through fourth impurity diffusion layers that are formed at predetermined intervals in surface portions of the semiconductor substrate;
a first gate electrode that is formed on a portion of the semiconductor substrate, the portion being located between the first impurity diffusion layer and the second impurity diffusion layer;
a second gate electrode that is formed on a portion of the semiconductor substrate, the portion being located between the second impurity diffusion layer and the third impurity diffusion layer;
a third gate electrode that is formed on a portion of the semiconductor substrate, the portion being located between the third impurity diffusion layer and the fourth impurity diffusion layer;
a first insulating film that is formed on the semiconductor substrate, to cover the first through third gate electrodes;
a first contact plug that penetrates through the first insulating film, and is in contact with the first impurity diffusion layer;
a second contact plug that penetrates through the first insulating film, and is in contact with the second impurity diffusion layer;
a third contact plug that penetrates through the first insulating film, and is in contact with the third impurity diffusion layer;
a fourth contact plug that penetrates through the first insulating film, and is in contact with the fourth impurity diffusion layer;
a first metal film that is formed on the first contact plug;
a second metal film that is formed on the second contact plug;
a third metal film that is formed on the third contact plug, a portion of the first insulating film located between the third contact plug and the fourth contact plug, and the fourth contact plug;
a capacitor lower electrode film that is formed on the first metal film;
a fourth metal film that is formed on the third metal film, and is made of the same material as the capacitor lower electrode film;
a ferroelectric film that is formed on a region of the capacitor lower electrode film, the region being located above the first gate electrode;
a capacitor upper electrode film that is formed on the ferroelectric film;
a second insulating film that is formed on the capacitor lower electrode film, to cover the capacitor upper electrode film and the ferroelectric film;
a third insulating film that is formed on the fourth metal film, and is made of the same material as the second insulating film;
a fourth insulating film that is formed to cover the second insulating film, the third insulating film, and the second metal film;
a fifth contact plug that penetrates through the fourth insulating film and the second insulating film, and is in contact with the capacitor upper electrode film;
a sixth contact plug that penetrates through the fourth insulating film, and is in contact with the second metal film;
a seventh contact plug that penetrates through the fourth insulating film and the third insulating film, and is in contact with the fourth metal film;
a fifth metal film that is formed on the fifth contact plug, a portion of the fourth insulating film located between the fifth contact plug and the sixth contact plug, and the sixth contact plug; and
a sixth metal film that is formed on the seventh contact plug, and is connected to a bit line.

2. The semiconductor memory device according to claim 1, wherein the second insulating film and the third insulating film contain Al₂O₃.

3. The semiconductor memory device according to claim 1, further comprising
a seventh metal film that is formed on the second metal film, and is made of the same material as the capacitor lower electrode film and the fourth metal film,
wherein the sixth contact plug is in contact with the seventh metal film.

4. The semiconductor memory device according to claim 1, further comprising:
a second ferroelectric film that is formed on the fourth metal film, and is made of the same material as the ferroelectric film; and
a seventh metal film that is formed on the second ferroelectric film, and is made of the same material as the capacitor upper electrode film,
wherein the seventh contact plug penetrates through the fourth insulating film, the third insulating film, the seventh metal film, and the second ferroelectric film, and is in contact with the fourth metal film.

5. The semiconductor memory device according to claim 1, wherein a transistor including the second impurity diffusion layer, the third impurity diffusion layer, and the second gate electrode is a select transistor.

6. The semiconductor memory device according to claim 1, wherein a transistor including the third impurity diffusion layer, the fourth impurity diffusion layer, and the third gate electrode is a dummy transistor.

7. A method for manufacturing a semiconductor memory device, comprising:
forming first through third gate electrodes at predetermined intervals on a semiconductor substrate via a gate insulating film;
forming a first impurity diffusion layer, a second impurity diffusion layer, a third impurity diffusion layer, and a fourth impurity diffusion layer in surface portions of the semiconductor substrate by injecting impurities into the semiconductor substrate, with the first through third gate electrodes serving as masks, the first impurity diffusion layer and the second impurity diffusion layer sandwiching the first gate electrode, the third impurity diffusion layer and the fourth impurity diffusion layer sandwiching the third gate electrode;
forming a first insulating film to cover the first through third gate electrodes and the first through fourth impurity diffusion layers;
forming first through fourth openings that penetrate through the first insulating film, and expose upper faces of the first through fourth impurity diffusion layers;
forming first through fourth contact plugs by filling the first through fourth openings with a first metal film;
forming a second insulating film on the first through fourth contact plugs and the first insulating film;
forming a fifth opening to expose an upper face of the first contact plug, a sixth opening to expose an upper face of the second contact plug, and a seventh opening to expose an upper face of the third contact plug, an upper face of the first insulating film located between the third contact plug and the fourth contact plug, and an upper face of the fourth contact plug;
forming first through third wirings by filling the fifth through seventh openings with a second metal film;
forming a capacitor lower electrode film on the first through third wirings and the second insulating film;
forming a ferroelectric film on the capacitor lower electrode film;
forming a capacitor upper electrode film on the ferroelectric film;
removing portions of the capacitor upper electrode film and the ferroelectric film, the portions being located outside a region above the first gate electrode;
forming a third insulating film to cover the capacitor upper electrode film and the ferroelectric film, the third insulating film being formed on regions of the capacitor lower electrode film, the regions being located above the first wiring and the third wiring;
partially removing the capacitor lower electrode film, with the third insulating film serving as a mask;
forming a fourth insulating film to cover the third insulating film, the second insulating film, and the second wiring;
forming an eighth opening that penetrates through the fourth insulating film and the third insulating film, and exposes an upper face of the capacitor upper electrode film;
forming a fifth contact plug by filling the eighth opening with a third metal film;
forming a ninth opening that penetrates through the fourth insulating film and exposes an upper face of the second wiring, and a tenth opening that penetrates through the fourth insulating film and the third insulating film, and exposes an upper face of the capacitor lower electrode film located in a region above the fourth contact plug;
forming sixth and seventh contact plugs by filling the ninth and tenth openings with a fourth metal film;
forming a fifth insulating film on the fifth through seventh contact plugs and the fourth insulating film;
forming an eleventh opening that exposes an upper face of the fifth contact plug, an upper face of the fourth insulating film located between the fifth contact plug and the sixth contact plug, and an eleventh opening that exposes an upper face of the sixth contact plug, and a twelfth opening that exposes an upper face of the seventh contact plug; and
forming fourth and fifth wirings by filling the eleventh and twelfth openings with a fifth metal film.

8. The method according to claim 7, wherein the third insulating film contains Al₂0₃.

9. The method according to claim 7, wherein:
the third insulating film is also formed in a region located above the second wiring; and
the ninth opening is formed to expose an upper face of the capacitor lower electrode film located in a region above the second wiring.

10. The method according to claim 7, wherein:
portions of the capacitor upper electrode film and the ferroelectric film are left in a region located above the fourth contact plug; and
the tenth opening is formed to penetrate through the fourth insulating film, the third insulating film, the capacitor upper electrode film, and the ferroelectric film.
